(19) United States
(12) Patent Application Publication
(10) Pub. No.: US 2026/0026246 A1
(43) Pub. Date: Jan. 22, 2026

(54) DISPLAY APPARATUS HAVING A PIXEL LENS ON A LIGHT-EMITTING DEVICE

(71) Applicant: LG Display Co., Ltd., Seoul (KR)

(72) Inventors: You Yong JIN, Paju-si (KR); Joo Bong HYUN, Paju-si (KR); Keong Jin LEE, Paju-si (KR)

(73) Assignee: LG Display Co., Ltd., Seoul (KR)

(21) Appl. No.: 19/267,290

(22) Filed: Jul. 11, 2025

(30) Foreign Application Priority Data
Jul. 19, 2024 (KR) 10-2024-0095908

(51) Int. Cl. H10K 59/80

(52) U.S. Cl. CPC H10K 59/879; H10K 59/873; H10K 59/8792

(57) ABSTRACT

A display apparatus can include a light-emitting device on an emission area of a device substrate, a lower barrier pattern on the light-emitting device, the lower barrier pattern including a lower opening overlapping with the emission area, an upper barrier pattern on the lower barrier pattern, the upper barrier pattern including an upper opening overlapping with the lower opening, a pixel lens on the upper barrier pattern, the pixel lens overlapping with the emission area, and an optical insulating layer disposed between the lower barrier pattern and the upper barrier pattern, the optical insulating layer including a lens groove filled by the pixel lens. Also, the lens groove can overlap with an end of the upper barrier pattern. Further, an inner periphery of the upper opening in the upper barrier pattern can circumferentially encompass and retain the lens.

### CROSS-REFERENCE TO RELATED APPLICATIONS

This application claims priority to Korean Patent Application No. 10-2024-0095908, filed in the Republic of Korea on Jul. 19, 2024, the entirety of which is hereby incorporated by reference into the present application as if fully set forth herein.

### BACKGROUND

### Field of the Invention

The present disclosure relates to a display apparatus in which a pixel lens is disposed on a light-emitting device.

### Discussion of the Related Art

Generally, a display apparatus provides an image to a user. For example, the display apparatus can include light-emitting devices. Each of the light-emitting devices can emit light displaying a specific color. For example, each of the light-emitting devices can include a light-emitting unit between a first electrode and a second electrode.

The display apparatus can include pixel lenses overlapping with the light-emitting devices. The light emitted from each light-emitting device can be concentrated by one of the pixel lenses. The pixel lenses can be formed of a photosensitive material. For example, a step of forming the pixel lenses can include a step of forming a preliminary layer made of a photosensitive material, a step of forming lens patterns by patterning the preliminary layer, and a step of reflowing the lens patterns.

The step of forming the lens patterns can include a step of irradiating light to a portion of the preliminary layer. However, in the display apparatus, if light is not sufficiently irradiated to a portion of the preliminary layer, a side surface of each lens pattern can be formed in an inverted tapered shape. Thus, in the display apparatus, an adhesive force between each lens pattern and a layer disposed under the lens patterns can be reduced. For example, in the display apparatus, some of the lens patterns and/or the pixel lenses can be lost by an external impact or a subsequent process. For example, existing display devices often suffer from issues where a pixel lens peels off or detaches, which impairs the optical and structural integrity of the display device. Thus, a needs exists for a display device having a configuration that can better secure pixels lenses, prevent pealing issues, and provide improved device integrity and enhanced manufacturing stability and efficiency.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of stably forming the pixel lenses on the light-emitting devices.

Another object of the present disclosure is to provide a display apparatus capable of preventing the loss of the lens patterns and/or the pixel lenses.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus including a device substrate. A light-emitting device is disposed on an emission area of the device substrate. A lower barrier pattern is disposed on the light-emitting device. The lower barrier pattern includes a lower opening overlapping with the emission area. An upper barrier pattern is disposed on the lower barrier pattern. The upper barrier pattern includes an upper opening overlapping with the lower opening. A pixel lens is disposed on the upper barrier pattern. The pixel lens includes a region overlapping with the emission area. An optical insulating layer is disposed between the lower barrier pattern and the upper barrier pattern. The optical insulating layer includes a lens groove. The lens groove filled by the pixel lens overlaps an end of the upper barrier pattern toward the emission area.

The upper opening of the upper barrier pattern can have a different size than the lower opening of the lower barrier pattern.

The lens groove of the optical insulating layer can have a larger size than the upper opening of the upper barrier pattern. A bottom surface of the lens groove can overlap with the emission area.

The bottom surface of the lens groove overlapping with the emission area can have a flat shape.

The lens groove can include a sidewall overlapping with the upper barrier pattern. The sidewall of the lens groove overlapping with the upper barrier pattern can have a curved shape.

A lower surface of the upper barrier pattern toward the device substrate can be in contact with the pixel lens in the lens groove.

The upper barrier pattern can include a different material from the lower barrier pattern.

The upper barrier pattern can include a conductive material.

In another embodiment, there is provided a display apparatus including a light-emitting device on an emission area of a device substrate. An optical insulating layer is disposed on the light-emitting device. A first lens groove is disposed at an upper surface of the optical insulating layer opposite to the device substrate. An upper barrier pattern is disposed on the optical insulating layer. The upper barrier pattern includes an upper opening overlapping with the emission area. A pixel lens is disposed on the upper barrier pattern. The pixel lens includes a region overlapping with the upper opening. The upper barrier pattern includes an end overlapping with the first lens groove. The end of the upper barrier pattern overlapping with the first lens groove is surrounded by the pixel lens.

The first lens groove can extend along an edge of the emission area.

The optical insulating layer can include a second lens groove spaced apart from the first lens groove. The second lens groove can be disposed in the upper opening of the upper barrier pattern. A sidewall of the second lens groove can have an inclined shape with respect to a lower surface of the optical insulating layer toward the device substrate. A width of the second lens groove can increase as it approaches the pixel lens.

A bottom surface of the second lens groove toward the device substrate can have a flat shape.

A size of the second lens groove can be different from a size of the first lens groove.

A sidewall of the first lens groove can have an inclined shape with respect to the lower surface of the optical insulating layer. The sidewall of the second lens groove can have a same inclination angle as the sidewall of the first lens groove.

An encapsulation structure can be disposed between the device substrate and the optical insulating layer. The encapsulation structure can cover the light-emitting device. A lower barrier pattern can be disposed between the encapsulation structure and the optical insulating layer. The lower barrier pattern can include a lower opening overlapping with the emission area. The first lens groove can be disposed outside the lower opening of the lower barrier pattern.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of K1 region in FIG. 1 according to an embodiment of the present disclosure;

FIG. 4 is a view taken along I-I′ of FIG. 3 according to an embodiment of the present disclosure;

FIGS. 5 to 8 are views sequentially showing a method of forming the display apparatus according to an embodiment of the present disclosure; and

FIGS. 9 to 24 are views showing the display apparatus according to embodiments of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components. The features of various embodiments of the present disclosure can be partially or entirely coupled to or combined with each other and can be interlocked and operated in technically various ways, and the embodiments can be carried out independently of or in association with each other. Also, the term “can” used herein includes all meanings and definitions of the term “may.”

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

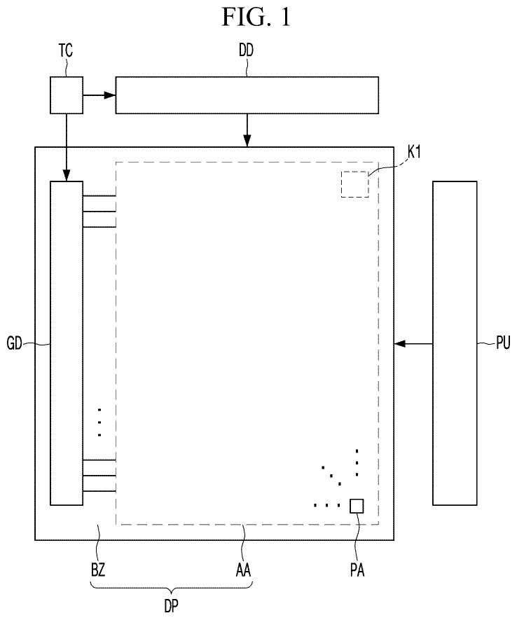

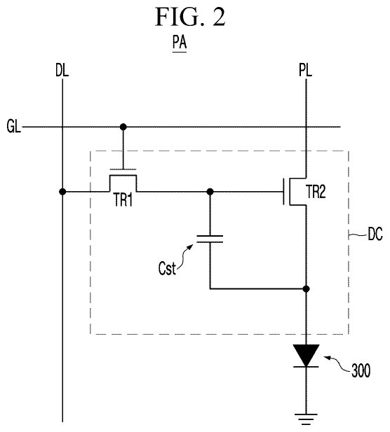

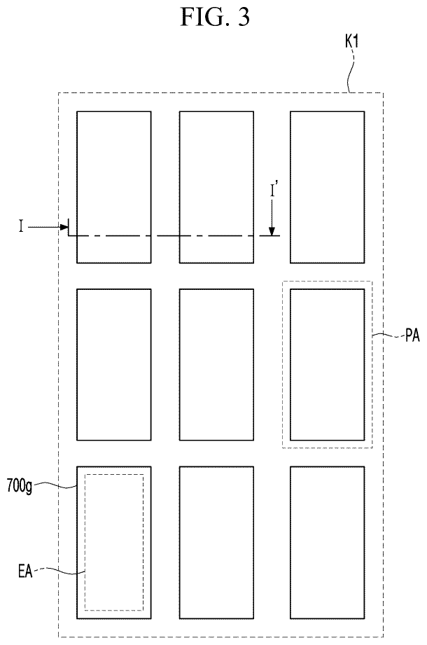

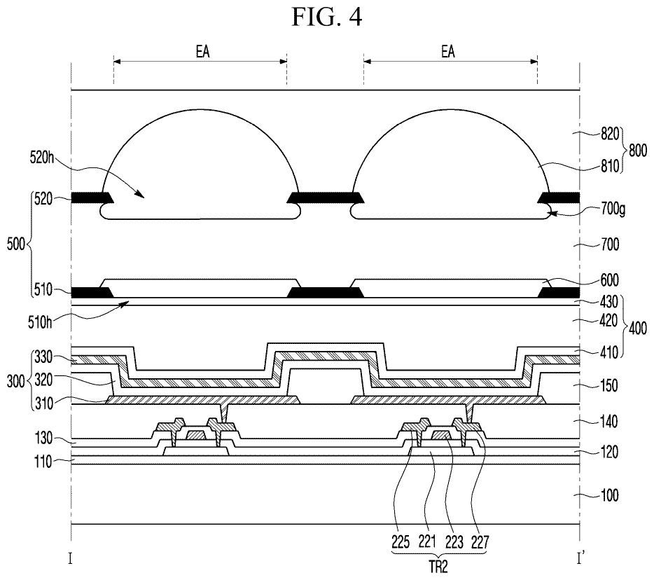

FIG. 1 is a view schematically showing a display apparatus according to an embodiment of the present disclosure. FIG. 2 is a view showing a circuit of a pixel area in the display apparatus according to the embodiment of the present disclosure. FIG. 3 is an enlarged view of K1 region in FIG. 1. FIG. 4 is a view taken along I-I′ of FIG. 3 according to the embodiment of the present disclosure.

Referring to FIGS. 1 to 4, the display apparatus according to the embodiment of the present disclosure can include a display panel DP. The display panel DP can generate an image provided to a user. For example, a plurality of pixel areas PA can be disposed in the display panel DP. Various signals can be applied in each pixel area PA through signal wirings GL, DL and PL. For example, the signal wirings GL, DL and PL can include gate lines GL applying a gate signal, data lines DL applying a data signal, and power voltage supply lines PL supplying a power voltage.

The gate lines GL can be electrically connected to a gate driver GD. The data lines DL can be electrically connected to a data driver DD. The power voltage supply lines PL can be electrically connected to a power unit PU. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC.

The display panel DP can include an active area AA in which the pixel areas PA are disposed, and a bezel area BZ being disposed outside the active area AA. The gate driver GD, the data driver DD, the power unit PU and the timing controller TC can be disposed outside the active area AA. For example, each of the signal wirings GL, DL and PL can include a region disposed on the bezel area BZ. The active area AA can be surrounded by the bezel area BZ.

At least one of the gate driver GD, the data driver DD, the power unit PU and the timing controller TC can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color. For example, a light-emitting device 300 and a driving circuit DC electrically connected to the light-emitting device 300 can be disposed in each pixel area PA. The driving circuit DC of each pixel area PA can supply a driving current corresponding to the data signal to the light-emitting device 300 of the corresponding pixel area PA according to the gate signal for one frame. For example, the driving circuit DC of each pixel area PA can include a first thin film transistor TR1, a second thin film transistor TR2 and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. The first gate electrode of each pixel area PA can be electrically connected to one of the gate lines GL, and the first drain electrode of each pixel area PA can be electrically connected to one of the date lines DL.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can have a same structure as the first thin film transistor TR1 of the corresponding pixel area PA. For example, the second thin film transistor TR2 of each pixel area PA can include a second semiconductor pattern 221, a second gate electrode 223, a second drain electrode 225 and a second source electrode 227. The second gate electrode 223 of each pixel area PA can be electrically connected to the first source electrode of the corresponding pixel area PA, and the second drain electrode 225 of each pixel area PA can be electrically connected to one of the power voltage supply lines PL.

The second semiconductor pattern 221 can include a semiconductor material. For example, the second semiconductor pattern 221 can include a lower temperature poly-Si (LTPS) or an oxide semiconductor, such as IGZO. The second semiconductor pattern 221 can include a drain region, a channel region and a source region. The channel region can be disposed between the drain region and the source region. The drain region and the source region can have a smaller resistance than the channel region. For example, the drain region and the source region can include a conductive region of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap with the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the drain region of the second semiconductor pattern 221. The second drain electrode 225 can be insulated from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the source region of the second semiconductor pattern 221. The second source electrode 227 can be spaced apart from the second drain electrode 225. The second source electrode 227 can be insulated from the second gate electrode 223.

The first source electrode can include a same material as the second source electrode 227. The first source electrode can be disposed on a same layer as the second source electrode 227. The first source electrode can be formed by a same process as the second source electrode 227. For example, the first source electrode can be formed simultaneously with the second source electrode 227. That is, in the display apparatus according to the embodiment of the present disclosure, the second drain electrode 225 and the second source electrode 227 can be formed simultaneously with the first drain electrode and the first source electrode. Thus, in the display apparatus according to the embodiment of the present disclosure, the process efficiency can be improved.

The storage capacitor Cst of each pixel area PA can maintain a voltage applied to the second gate electrode 223 of the corresponding pixel area PA for one frame. For example, the storage capacitor Cst of each pixel area PA can be electrically connected to the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA can include a first capacitor electrode electrically connected to the second gate electrode 233 of the corresponding pixel area PA, and a second capacitor electrode electrically connected to the second source electrode 227 of the corresponding pixel area PA.

The first capacitor electrode and the second capacitor electrode of each pixel area PA can be formed using a process of forming the first thin film transistor TR1 and the second thin film transistor TR2 of the corresponding pixel area PA. For example, the first capacitor electrode of each pixel area PA can be formed simultaneously with the second gate electrode 223 of the corresponding pixel area PA, and the second capacitor electrode of each pixel area PA can be formed simultaneously with the second source electrode 227 of the corresponding pixel area PA. Thus, in the display apparatus according to the embodiment of the present disclosure, a process of forming the driving circuit DC of each pixel area PA can be simplified.

The driving circuit DC of each pixel area PA can be disposed on a device substrate 100. For example, the device substrate 100 can support the first thin film transistor TR1, the second thin film transistor TR2 and the storage capacitor Cst of each pixel area PA. The device substrate 100 can include an insulating material. For example, the device substrate 100 can include glass or plastic.

At least one or more insulating layers 110, 120, 130, 140 and 150 for preventing undesirable electrical connection or short circuits can be disposed on the device substrate 100. For example, a buffer insulating layer 110, a gate insulating layer 120, an interlayer insulating layer 130, an over-coat layer 140 and a bank insulating layer 150 can be disposed on the device substrate 100.

The buffer insulating layer 110 can be disposed close to the device substrate 100. The buffer insulating layer 110 can prevent pollution due to the device substrate 100 in a process of forming the driving circuit DC of each pixel area PA. For example, an upper surface of the device substrate 100 toward the driving circuit DC of each pixel area PA can be covered by the buffer insulating layer 110. The driving circuit DC of each pixel area PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The first gate electrode of each pixel area PA can be insulated from the first semiconductor pattern of the corresponding pixel area PA by the gate insulating layer 120. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The interlayer insulating layer 130 can be disposed on the gate insulating layer 120. The first drain electrode and the first source electrode of each pixel area PA can be insulated from the first gate electrode of the corresponding pixel area PA by the interlayer insulating layer 130. The second drain electrode 225 and the second source electrode 227 of each pixel area PA can be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can include an inorganic insulating material.

The over-coat layer 140 can be disposed on the interlayer insulating layer 130. The over-coat layer 140 can remove a thickness difference due to the driving circuit DC of each pixel area PA. For example, an upper surface of the over-coat layer 140 opposite to the device substrate 100 can be flat. The upper surface of the over-coat layer 140 can be parallel to the upper surface of the device substrate 100. The over-coat layer 140 can include an insulating material. The over-coat layer 140 can include a different material from the buffer insulating layer 110, the gate insulating layer 120 and the interlayer insulating layer 130. The over-coat layer 140 can include a material having a relatively high fluidity. For example, the over-coat layer 140 can include an organic insulating material.

The light-emitting device 300 of each pixel area PA can be disposed on the over-coat layer 140. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the over-coat layer 140 of the corresponding pixel area PA.

The first electrode 310 can include a conductive material. The first electrode 310 can include a material having high reflectance. For example, the first electrode 310 can include a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting unit 320 can generate light having luminance corresponding to a voltage difference between the first electrode 310 and the second electrode 330. For example, the light-emitting unit 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting unit 320 can have a multi-layer structure. For example, the light-emitting unit 320 can include at least one of a hole injection layer (HIL), a hole transport layer (HTL), an electron transport layer (ETL) and an electron injection layer (EIL). Thus, in the display apparatus according to the embodiment of the present disclosure, the efficiency of the light-emitting unit 320 can be improved.

The second electrode 330 can include a conductive material. The second electrode 330 can include a different material from the first electrode 310. A transmittance of the second electrode 330 can be greater than a transmittance of the first electrode 310. For example, the second electrode 330 can be a transparent electrode made of a transparent conductive material, such as ITO and IZO. Thus, in the display apparatus according to the embodiment of the present disclosure, the light generated by the light-emitting unit 320 can be emitted outside through the second electrode 330. The second electrode 330 can have a lower work-function than the first electrode 310. For example, the first electrode 310 can function as anode electrode, and the second electrode 330 can function as cathode electrode.

The bank insulating layer 150 can be disposed on the over-coat layer 140. The bank insulating layer 150 can define an emission area EA in each pixel area PA. For example, the bank insulating layer 150 can partially expose the first electrode 310 of each pixel area PA. The light-emitting unit 320 and the second electrode 330 of each pixel area PA can be stacked on a portion of the corresponding first electrode 310 exposed by the bank insulating layer 150. For example, the light-emitting unit 320 and the second electrode 330 of each pixel area PA can include a region overlapping with the emission area EA of the corresponding pixel area PA. The light-emitting unit 320 can be in direct contact with the first electrode 310 and the second electrode 330 on the emission area EA of each pixel area PA. The light-emitting unit 320 and the second electrode 330 of each pixel area PA can extend on the bank insulating layer 150. Thus, in the display apparatus according to the embodiment of the present disclosure, light is not generated outside the emission area EA defined in each pixel area PA. The bank insulating layer 150 can include an insulating material. For example, the bank insulating layer 150 can include an organic insulating material. The bank insulating layer 150 can include a different material from the over-coat layer 140.

The first electrode 310 of each pixel area PA can be electrically connected to the driving circuit DC of the corresponding pixel area PA. For example, the first electrode 310 of each pixel area PA can be in direct contact with the second source electrode 227 of the corresponding pixel area PA by penetrating the over-coat layer 140. A region where the first electrode 310 of each pixel area PA is electrically connected to the second source electrode 227 of the corresponding pixel area PA can overlap with the bank insulating layer 150. For example, a portion of the first electrode 310 overlapping with the emission area EA in each pixel area PA can be in direct contact with the upper surface of the over-coat layer 140. Thus, in the display apparatus according to the embodiment of the present disclosure, a portion of the first electrode 310 overlapping with the emission area EA in each pixel area PA can have a flat shape. Therefore, in the display apparatus according to the embodiment of the present disclosure, the luminance deviation depending on the generation location of the light emitted from the emission area EA of each pixel area PA can be prevented.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can be in direct contact with the second electrode 330 of adjacent pixel area PA. For example, the second electrode 330 can be laid down as a continuous layer or sheet across a plurality of pixels. Thus, in the display apparatus according to the embodiment of the present disclosure, a process of forming the second electrode 330 in each pixel area PA can be simplified. And, in the display apparatus according to the embodiment of the present disclosure, the luminance of the light generated from the light-emitting unit 320 of each pixel area PA can be adjusted by the data signal applied to the pixel driving circuit DC of the corresponding pixel area PA.

The light emitted from the light-emitting device 300 of each pixel area PA can display a same color as the light-emitting device 300 of adjacent pixel area PA. For example, the light-emitting device 300 of each pixel area PA can emit a white light. The light-emitting unit 320 of each pixel area PA can have a stacked structure same as the light-emitting unit 320 of adjacent pixel area PA. The light-emitting unit 320 of each pixel area PA can be formed by a same process of the light-emitting unit 320 of adjacent pixel area PA. For example, the light-emitting unit 320 of each pixel area PA can be formed simultaneously with the light-emitting unit 320 of adjacent pixel area PA. Thus, in the display apparatus according to the embodiment of the present disclosure, a process of forming the light-emitting unit 320 in each pixel area PA can be simplified. Therefore, in the display apparatus according to the embodiment of the present disclosure, the process efficiency can be improved.

An encapsulation structure 400 can be disposed on the light-emitting device 300 of each pixel area PA. The encapsulation structure 400 can prevent the damage of the light-emitting devices 300 in each pixel area PA due to external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the light-emitting device 300 in each pixel area PA due to the external impact and moisture can be effectively prevented. A thickness difference due to the light-emitting device 300 of each pixel area PA can be removed by the second encapsulating layer 420 of the encapsulation structure 400. For example, an upper surface of the encapsulation structure 400 opposite to the device substrate 100 can be flat. The upper surface of the encapsulation structure 400 can be parallel to the upper surface of the device substrate 100.

A barrier structure 500 can be disposed on the encapsulation structure 400. The barrier structure 500 can have a multi-layer structure. For example, the barrier structure 500 can include a lower barrier pattern 510 and an upper barrier pattern 520 disposed on the lower barrier pattern 510. The lower barrier pattern 510 and the upper barrier pattern 520 can include a material capable of blocking light. For example, the lower barrier pattern 510 and the upper barrier pattern 520 can include a black dye, such as carbon black. The upper barrier pattern 520 can include a same material as the lower barrier pattern 510. According to an embodiment, the lower barrier pattern 510 and the upper barrier pattern 520 can be referred to as black matrices.

The upper barrier pattern 520 can overlap with the lower barrier pattern 510. The lower barrier pattern 510 and the upper barrier pattern 520 can be disposed between adjacent emission areas EA. For example, the lower barrier pattern 510 and the upper barrier pattern 520 can overlap with the bank insulating layer 150. The lower barrier pattern 510 and the upper barrier pattern 520 can be spaced apart from the emission area EA of each pixel area PA. For example, the lower barrier pattern 510 can include lower openings 510h overlapping with the emission areas EA of the pixel areas PA, and the upper barrier pattern 520 can include upper openings 520h overlapping with the lower openings 510h. Thus, in the display apparatus according to the embodiment of the present disclosure, the light generated by the light-emitting device 300 of each pixel area PA can be emitted outside by passing through one of the lower openings 510h of the lower barrier pattern 510 and one of the upper openings 520h of the upper barrier pattern 520. That is, in the display apparatus according to the embodiment of the present disclosure, the travelling direction of the light emitted from the light-emitting device 300 of each pixel area PA can be restricted by the lower barrier pattern 510 and the upper barrier pattern 520. For example, an image realized by the light emitted from the light-emitting device 300 of each pixel area PA can be recognized by people around the user. Therefore, in the display apparatus according to the embodiment of the present disclosure, the image having a narrow viewing angle can be provided to the user, which can improve privacy.

In the display apparatus according to the embodiment of the present disclosure, the image having various colors can be provided to the user. For example, a color filter 600 can be disposed on the emission area EA of each pixel area PA. The light emitted from the light-emitting device 300 of each pixel area PA can realize a specific color by the color filter 600 of the corresponding pixel area PA. For example, the color filter 600 of each pixel area PA can include a different material from the color filter 600 of adjacent pixel area PA. The color filter 600 of each pixel area PA can be disposed on a path of the light emitted from the light-emitting device 300 of the corresponding pixel area PA. For example, the lower opening 510h of each pixel area PA can be filled by the color filter 600 of the corresponding pixel area PA. The lower opening 510h of each pixel area PA can have a size corresponding to the emission area EA of the corresponding pixel area PA. For example, the lower opening 510h of each pixel area PA can have a same size as the emission area EA of the corresponding pixel area PA. The color filter 600 of each pixel area PA can have a larger size than the emission area EA of the corresponding pixel area PA. For example, an end of the color filter 600 on each pixel area PA can overlap with the lower barrier pattern 510. That is, in the display apparatus according to the embodiment of the present disclosure, the lower barrier pattern 510 can function as a black matrix. Thus, in the display apparatus according to the embodiment of the present disclosure, the light leakage due to the light that does not pass through the color filters 600 can be prevented.

The upper barrier pattern 520 can be spaced apart from the lower barrier pattern 510. For example, an optical insulating layer 700 can be disposed between the lower barrier pattern 510 and the upper barrier pattern 520. The optical insulating layer 700 can include an insulating material. The optical insulating layer 700 can include a transparent material. For example, the optical insulating layer 700 can include an inorganic insulating material and/or an organic insulating material. The optical insulating layer 700 can cover the lower barrier pattern 510 and the color filters 600. For example, a thickness difference due to the lower barrier pattern 510 and the color filters 600 can be removed by the optical insulating layer 700. An upper surface of the optical insulating layer 700 opposite to the encapsulation structure 400 can be flat. For example, the upper surface of the optical insulating layer 700 can be parallel to the upper surface of the encapsulation structure 400. The lower barrier pattern 510 and the color filters 600 can be in direct contact with the optical insulating layer 700. For example, the lower barrier pattern 510 and the color filters 600 can directly contact a lowermost surface of the optical insulating layer 700.

The upper barrier pattern 520 can be disposed on the upper surface of the optical insulating layer 700. For example, a lower surface of the upper barrier pattern 520 toward the encapsulation structure 400 can be in direct contact with the upper surface of the optical insulating layer 700. The optical insulating layer 700 can extend between the lower openings 510h of the lower barrier pattern 510 and the upper openings 520h of the upper barrier pattern 520. For example, the light emitted through the lower opening 510h of each pixel area PA can pass through the optical insulating layer 700. The emission area EA of each pixel area PA can overlap with a portion of the optical insulating layer 700. Thus, in the display apparatus according to the embodiment of the present disclosure, an optical distance of the light emitted from the light-emitting device 300 of each pixel area PA can be controlled by a thickness of the optical insulating layer 700. That is, in the display apparatus according to the embodiment of the present disclosure, the light emitted from the light-emitting device 300 of each pixel area PA can have a sufficient optical distance by the optical insulating layer 700.

The upper opening 520h of each pixel area PA can have a size corresponding to the emission area EA of the corresponding pixel area PA. For example, the upper opening 520h of each pixel area PA can have a same size as the lower opening 510h of the corresponding pixel area PA. Thus, in the display apparatus according to the embodiment of the present disclosure, the upper openings 520h of the upper barrier pattern 520 can be formed by a same mask as the lower openings 510h of the lower barrier pattern 510. Therefore, in the display apparatus according to the embodiment of the present disclosure, the process efficiency can be improved (e.g., the number of manufacturing steps can be reduced).

An optical structure 800 can be disposed on the barrier structure 500 and the optical insulating layer 700. The optical structure 800 can include pixel lenses 810 and a lens passivation layer 820 disposed on the pixel lenses 810. The pixel lenses 810 can overlap with the emission areas EA of the pixel areas PA. For example, each of the pixel lenses 810 can overlap with one of the upper openings 520h of the upper barrier pattern 520. A surface of each pixel lens 810 opposite to the optical insulating layer 700 can have a curved shape (e.g., a domed shape, a rounded shape or a hemi-spherical shape, etc.). For example, a cross-section of the pixel lens disposed on each pixel area PA can have a semicircular shape. Thus, in the display apparatus according to the embodiment of the present disclosure, the light passing through the lower opening 510h and the upper opening 520h of each pixel area PA can be concentrated by the pixel lens 810 of the corresponding pixel area PA. Therefore, in the display apparatus according to the embodiment of the present disclosure, the frontal luminance of each pixel area PA can be increased.

The pixel lens 810 of each pixel area PA can have a larger size than the upper opening 520h of the corresponding pixel area PA. For example, the upper opening 520h of each pixel area PA can be filled by the pixel lens 810 of the corresponding pixel area PA. An edge of the pixel lens 810 disposed on each pixel area PA can overlap with the upper barrier pattern 520. Thus, in the display apparatus according to the embodiment of the present disclosure, all light passing through the upper opening 520h of each pixel area PA can be concentrated by the pixel lens 810 of the corresponding pixel area PA. Therefore, in the display apparatus according to the embodiment of the present disclosure, the efficiency of the light-emitting device 300 disposed on each pixel area PA can be improved.

The lens passivation layer 820 can prevent the damage of the pixel lenses 810 due to the external impact. For example, the pixel lens 810 of each pixel area PA can be covered by the lens passivation layer 820. The lens passivation layer 820 can include an insulating material. For example, the lens passivation layer 820 can include an inorganic insulating material and/or an organic insulating material. A thickness difference or step difference due to the pixel lens 810 of each pixel area PA can be removed by the lens passivation layer 820. For example, an upper surface of the lens passivation layer 820 opposite to the optical insulating layer 700 can be flat and uniform. The upper surface of the lens passivation layer 820 can be parallel to the upper surface of the device substrate 100.

The lens passivation layer 820 can be in direct contact with the pixel lens 810 of each pixel area PA. A refractive index of the lens passivation layer 820 can be equal to or a less than a refractive index of each pixel lens 810. Thus, in the display apparatus according to the embodiment of the present disclosure, a reflection of light at a boundary between each pixel lens 810 and the lens passivation layer 820 can be prevented. For example, in the display apparatus according to the embodiment of the present disclosure, the light passing through the upper opening 520h of each pixel area PA is not reflected toward the device substrate 100 due to a difference in the refractive index of the pixel lens 801 of the corresponding pixel area PA and the lens passivation layer 820. Therefore, in the display apparatus according to the embodiment of the present disclosure, the light extraction efficiency can be improved.

Lens grooves 700g can be disposed at or etched into the upper surface of the optical insulating layer 700 toward the optical structure 800. The lens grooves 700g can be a region where a portion of the optical insulating layer 700 is removed. The lens grooves 700g can overlap with the upper openings 520h of the upper barrier pattern 520. For example, each of the lens grooves 700g can overlap with the emission area EA of one of the pixel areas PA. The lens groove 700g disposed on each pixel area PA can have a larger size than the upper opening 520h of the corresponding pixel area PA. For example, a sidewall of the lens groove 700g on each pixel area PA can overlap with the upper barrier pattern 520. For example, an outer edge of the lens groove 700g can extend underneath a portion of the upper barrier pattern 520 (e.g., forming an under-cut area or an eave overhang part). Thus, in the display apparatus according to the embodiment of the present disclosure, an under-cut can be formed on each pixel area PA by the lens groove 700g of the corresponding pixel area PA and the upper barrier pattern 520. For example, according to an embodiment, the configuration of the display device can use the lens groove 700g and the upper barrier pattern 520 to create an under-cut portion in each pixel area, which can help lock the pixel lens securely in place (e.g., a ridged edge of the lens can be held firmly in place).

The pixel lens 810 of each pixel area PA can include a region disposed in the lens groove 700g of the corresponding pixel area PA. For example, the lens groove 700g of each pixel area PA can be filled by the pixel lens 810 of the corresponding pixel area PA. The lower surface of the upper barrier pattern 520 exposed by the lens groove 700g of each pixel area PA can be in direct contact with one of the pixel lenses 810. For example, the pixel lens 810 of each pixel area PA can completely fill the under-cut by the lens groove 700g of the corresponding pixel area PA and the upper barrier pattern 520. That is, in the display apparatus according to the embodiment of the present disclosure, an end of the upper barrier pattern 520 toward the emission area EA of each pixel area PA can be surrounded by the pixel lens 810 of the corresponding pixel area PA. Thus, in the display apparatus according to the embodiment of the present disclosure, the peeling of the pixel lens 810 on each pixel area PA due to the external impact can be prevented. In other words, the pixel lens 810 can be formed to have a lower lip or ridged edge that can be fixed securely in place by the overhang portion of the upper barrier pattern 520 due to undercut formed by the lens groove 700g and the upper barrier pattern 520 (e.g., forming a type of ringed clamp around the lens).

A bottom surface of the lens groove 700g on each pixel area PA can have a flat shape, but embodiments are not limited thereto. The bottom surface of the lens groove 700g on each pixel area PA can have a larger size than the upper opening 520h of the corresponding pixel area PA. For example, the upper opening 520h of each pixel area PA can overlap with the bottom surface of the lens groove 700g on the corresponding pixel area PA. The sidewall of the lens groove 700g on each pixel area PA can be disposed outside the upper opening 520h on the corresponding pixel area PA. That is, in the display apparatus according to the embodiment of the present disclosure, the bottom surface of the lens groove 700g on each pixel area PA can have a larger size or be wider than the emission area EA of the corresponding pixel area PA. Thus, in the display apparatus according to the embodiment of the present disclosure, a boundary surface of the optical insulating layer 700 and the pixel lens 810 on each pixel area PA can be flat. For example, in the display apparatus according to the embodiment of the present disclosure, a boundary surface of the optical insulating layer 700 and the pixel lens 810 on each pixel area PA can be parallel to the upper surface of the device substrate 100. Therefore, in the display apparatus according to the embodiment of the present disclosure, the scattering of the light passing through the bottom surface of the lens groove 700g on each pixel area PA can be prevented.

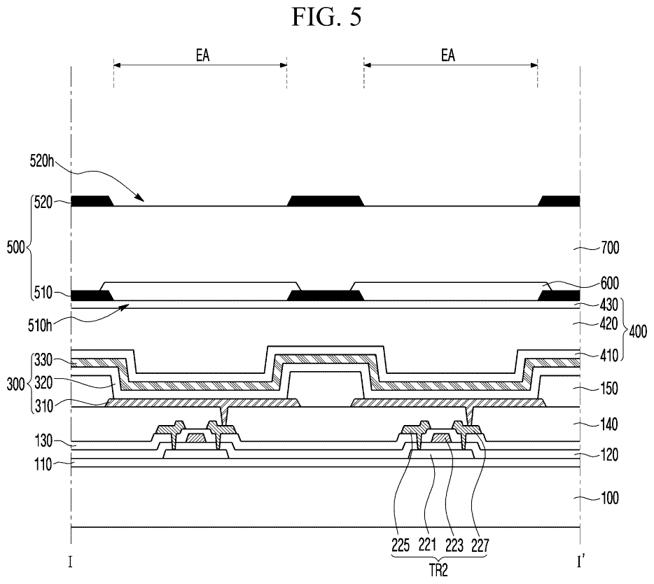

FIGS. 5 to 8 are views sequentially showing a method of forming the display apparatus according to the embodiment of the present disclosure.

The method of forming the display apparatus according to an embodiment of the present disclosure will be described with reference to FIGS. 4 to 8. First, as shown in FIG. 5, the method of forming the display apparatus according to the embodiment of the present disclosure can include a step of forming the buffer insulating layer 110, the gate insulating layer 120, the interlayer insulating layer 130, the driving circuits DC, the over-coat layer 140, the bank insulating layer 150, the light-emitting devices 300 and the encapsulation structure 400 on the device substrate 100, a step of forming the lower barrier pattern 510 including the lower openings 510h on the encapsulation structure 400, a step of forming the color filters 600 disposed in the lower openings 510h, a step of forming the optical insulating layer 700 covering the lower barrier pattern 510 and the color filter 600, and a step of the upper barrier pattern 520 including the upper opening 520h on the upper surface of the optical insulating layer 700.

The lower barrier pattern 510 and the upper barrier pattern 520 can be formed by a same process. For example, a step of forming the lower barrier pattern 510 and a step of forming the upper barrier pattern 520 can include a step of forming a barrier layer and a step of patterning the barrier layer. Thus, in the method of forming the display apparatus according to the embodiment of the present disclosure, the lower openings 510h of the lower barrier pattern 510 can partially expose the upper surface of the encapsulation structure 400, and the upper openings 520h of the upper barrier pattern 520 can be partially expose the upper surface of the optical insulating layer 700. The lower openings 510h and the upper openings 520h can overlap with the emission areas EA of the pixel areas PA. For example, a portion of the optical insulating layer 700 overlapping with the emission area EA of each pixel area PA can be disposed between the lower openings 510h and the upper openings 520h.

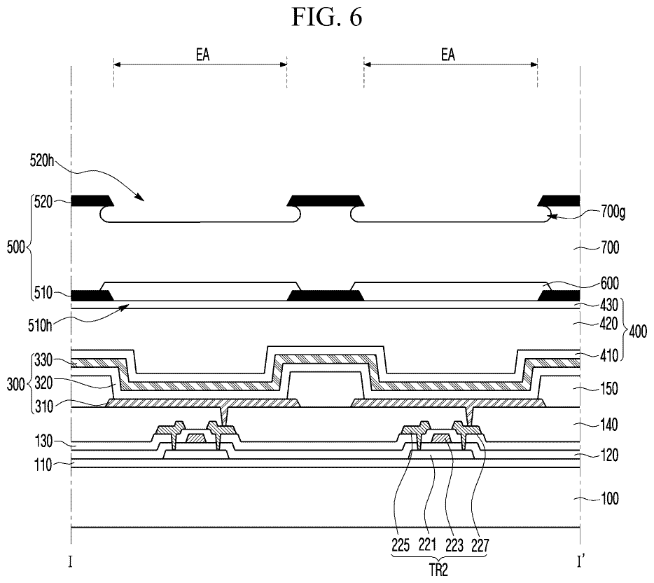

As shown in FIG. 6, the method of forming the display apparatus according to the embodiment of the present disclosure can include a step of forming the lens grooves 700g overlapping with the upper openings 520h at the upper surface of the optical insulating layer 700.

The step of forming the lens grooves 700g can include a step of removing a portion of the optical insulating layer 700 exposed by the upper openings 520h. For example, the step of forming the lens grooves 700g can use a same mask as a step of forming the upper openings 520h. Thus, in the method of forming the display apparatus according to the embodiment of the present disclosure, the step of forming the upper openings 520h of the upper barrier pattern 520 and the step of forming the lens grooves 700g of the optical insulating layer 700 can be performed in a same chamber. Therefore, in the method of forming the display apparatus according to the embodiment of the present disclosure, the production energy can be minimized by the process optimization.

Each of the lens grooves 700g can be formed to have a larger size than the corresponding upper opening 520h. For example, the step of forming the lens grooves 700g can include a step of over-etching the upper surface of the optical insulating layer 700. Thus, in method of forming the display apparatus according to the embodiment of the present disclosure, the under-cut can be formed on each pixel area PA by the lens groove 700g of the corresponding pixel area PA and the upper barrier pattern 520, without additional process. The sidewall of the lens groove 700g on each pixel area PA can be formed to have a curved shape. For example, in the method of forming the display apparatus according to the embodiment of the present disclosure, the sidewall of the lens groove 700g on each pixel area PA can have a convex shape toward the outside of the emission area EA defined in the corresponding pixel area PA. In other words, to form a secure “under-cut,” the lens grooves 700g can be created by over-etching the insulating layer 700 to make the grooves 700g larger than their corresponding openings 520h in the upper barrier pattern 520. Also, the sides of the groove can be shaped with a convex curve, bowing outward from the center of the pixel (e.g., a bulged portion that extends under an eave or overhang part of the upper barrier pattern 520).

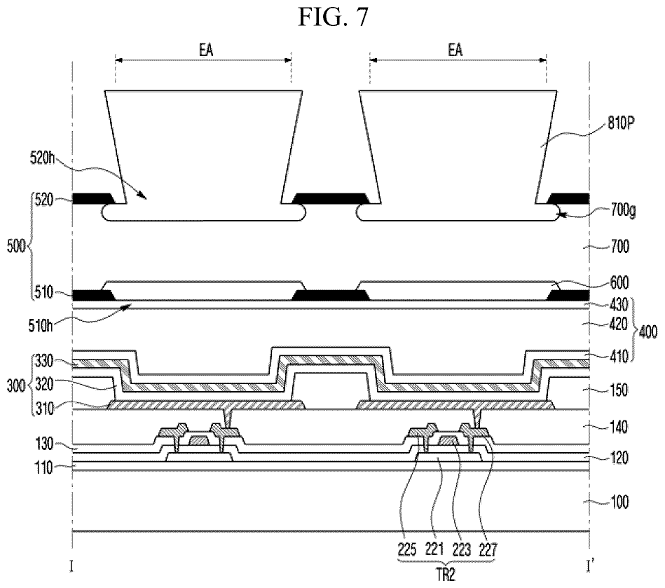

As shown in FIG. 7, the method of forming the display apparatus according to the embodiment of the present disclosure can include a step of forming lens patterns 810p on the lens grooves 700g of the optical insulating layer 700.

The lens patterns 810p can be formed of a photosensitive material. For example, the step of forming the lens patterns 810p can include a step of forming a photosensitive material layer on the upper barrier pattern 520 and the lens grooves 700g of the optical insulating layer 700, a step of irradiating light to a portion of the photosensitive material layer overlapping with the upper openings 520h, and a step of removing a portion of the photosensitive material layer where the light is not irradiated. The light is not sufficiently irradiated to a lower end of the photosensitive material layer disposed close to the optical insulating layer 700. For example, a side surface of each lens pattern 810 can have a negative taper shape (e.g., a reverse tapered shape relative to the substrate).

The lens grooves 700g can be completely filled by the photosensitive material layer. Although the light is not sufficiently irradiated to a portion of the photosensitive material layer disposed inside each lens groove 700g, the portion of the photosensitive material layer disposed inside each lens groove 700g may not be removed by a step of removing a portion of the photosensitive material layer. For example, each of the lens patterns 810p can include a region disposed inside one of the lens grooves 700g. The under-cut by the upper barrier pattern 520 and each lens groove 700g can be filled by a portion of the corresponding lens pattern 810p. Thus, in the method of forming the display apparatus according to the embodiment of the present disclosure, each of the lens patterns 810p can be physically fixed by the under-cut of the upper barrier pattern 520 and one of the lens grooves 700g. Therefore, in the method of forming the display apparatus according to the embodiment of the present disclosure, an issue of peeling off of the lens patterns 810p or detachment due to an external impact can be prevented. For example, in the method of forming the display apparatus according to the embodiment of the present disclosure, the loss of the lens patterns 810p due to a subsequent process such as a cleaning process performed after the formation of the lens patterns 810p can be prevented.

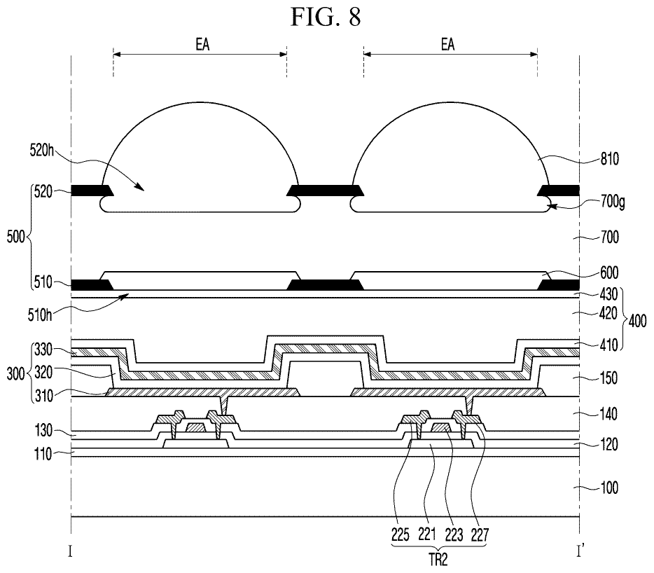

As shown in FIG. 8, the method of forming the display apparatus according to the embodiment of the present disclosure can include a step of forming the pixel lens 810 on the lens grooves 700g of the optical insulating layer 700.

The step of forming the pixel lens 810 can include a step of reflowing the lens patterns 810p. Thus, in the method of forming the display apparatus according to the embodiment of the present disclosure, an end of each pixel lens 810 can be formed on the upper barrier pattern 520. That is, in the method of forming the display apparatus according to the embodiment of the present disclosure, the end of the upper barrier pattern toward the emission area EA of each pixel area PA can be surrounded by the pixel lens 810 formed on the corresponding pixel area PA. In other words, part of the reverse tapered shape of the lens pattern 810p can be melted down to form a rounded lens as shown in FIG. 8, in which an outer edge or ridges of the lens can clamp around opposite sides of an overhang edge portion of the upper barrier pattern 520 in a vice grip like manner for securely fixing the lenses 810 in place. Therefore, in the method of forming the display apparatus according to the embodiment of the present disclosure, the pixel lens 810 of each pixel area PA can be firmly fixed on the corresponding pixel area PA.

As shown in FIG. 4, the method of forming the display apparatus according to the embodiment of the present disclosure can include a step of forming the optical structure including the pixel lenses 810 on the upper barrier pattern 520 and the optical insulating layer 700.

The step of forming the optical structure 800 can include a step of forming the lens passivation layer 820 on the pixel lenses 810. In the method of forming the display apparatus according to the embodiment of the present disclosure, the coupling force between the upper barrier pattern 520 and the pixel lens 810 of each pixel area PA can increase, such that the movement of each pixel lens 810 due to a process of forming the lens passivation layer 820 can be prevented. Therefore, in the method of forming the display apparatus according to the embodiment of the present disclosure, the degree of freedom in a process of forming the lens passivation layer 820 can be improved.

Accordingly, the display apparatus according to the embodiment of the present disclosure can include the light-emitting devices 300, the encapsulation structure 400, the barrier structure 500, the color filters 600, the optical insulating layer 700 and the pixel lenses 810 on the device substrate in which the emission area EA is defined in each pixel area PA, in which the barrier structure 500 can include the lower barrier pattern 510 disposed between the encapsulation structure 400 and the optical insulating layer 700 and the upper barrier pattern 520 disposed on the upper surface of the optical insulating layer 700, in which each of the lower barrier pattern 510 and the upper barrier pattern 520 can include the openings 510h and 520h overlapping with the emission area EA of each pixel area PA, and in which the pixel lens 810 of each pixel area PA can be formed to surround the end of the upper barrier pattern 520 toward the emission area EA of the corresponding pixel area PA. Thus, in the display apparatus according to the embodiment of the present disclosure, an issue of peeling away of the pixel lens 810 on each pixel area due to the external impact can be prevented. That is, in the display apparatus according to the embodiment of the present disclosure, the loss or detachment of the lens patterns 810p and/or the pixel lenses 810 due to a sequence process can be prevented. Therefore, in the display apparatus according to the embodiment of the present disclosure, the pixel lenses 810 on the pixel areas PA can be stably formed, manufacturing defects can be reduced and manufacturing yields can be increased. And, in the display apparatus according to the embodiment of the present disclosure, the production energy can be reduced by the process optimization.

The display apparatus according to the embodiment of the present disclosure is described that the driving circuit DC of each pixel area PA includes the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor pattern. The third gate electrode of each pixel area PA can be electrically connected to one of the gate lines GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in the configuration of the driving circuit DC in each pixel area PA can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

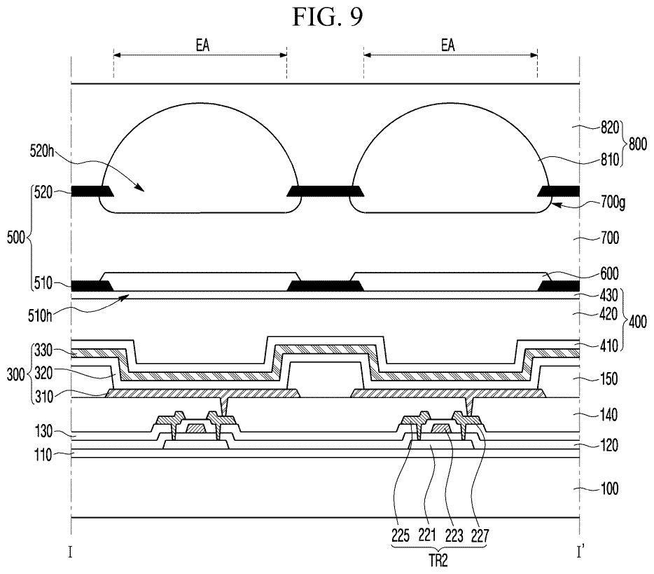

The display apparatus according to the embodiment of the present disclosure is described that the lens grooves 700g are formed by using the upper openings 520h of the upper barrier pattern 520. However, in the display apparatus according to another embodiment of the present disclosure, the lens grooves 700g can be formed by various processes. For example, in the display apparatus according to another embodiment of the present disclosure, the lens grooves 700g can be formed before the formation of the upper openings 520h of the upper barrier pattern 520. That is, in the display apparatus according to another embodiment of the present disclosure, the upper barrier pattern 520 can be formed on the upper surface of the optical insulating layer 700 in which the lens grooves 700g are formed. Thus, in the display apparatus according to another embodiment of the present disclosure, an edge of each lens groove 700g can have various shapes. For example, in the display apparatus according to another embodiment of the present disclosure, a cross-section of each lens groove 700g can have a concave shape toward the device substrate 100, as shown in FIG. 9. Therefore, in the display apparatus according to another embodiment of the present disclosure, the degree of freedom in a process of forming the lens groove 700g can be improved.

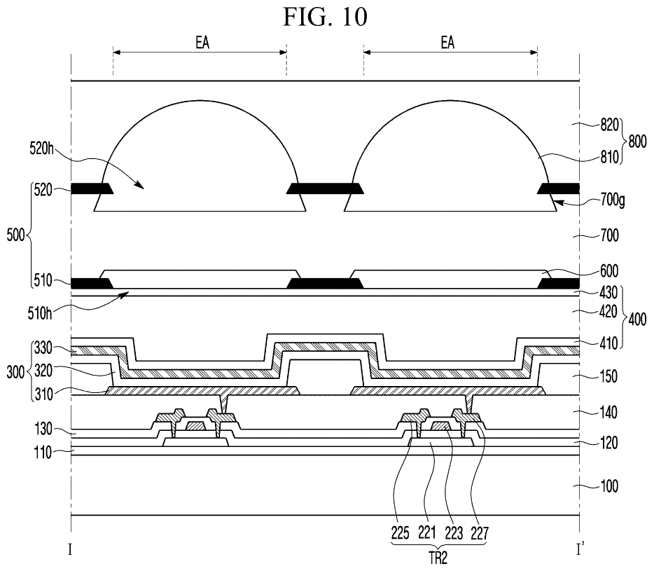

The display apparatus according to the embodiment of the present disclosure is described that the lens groove 700g of each pixel area PA includes the sidewall having a curved shape. However, in the display apparatus according to another embodiment of the present disclosure, the lens groove 700g of each pixel area PA can be formed in various ways. For example, in the display apparatus according to another embodiment of the present disclosure, the sidewall of the lens groove 700g on each pixel area PA can have a negative taper shape, as shown in FIG. 10. A width of the lens groove 700g on each pixel area PA can decrease as a distance from the device substrate 100 increases. Thus, in the display apparatus according to another embodiment of the present disclosure, the coupling force of the pixel lens 810 on each pixel area PA can be increased by the sidewall of the lens groove 700g on the corresponding pixel area PA. Therefore, in the display apparatus according to another embodiment of the present disclosure, the peeling of each pixel area PA due to the external impact can be effectively prevented.

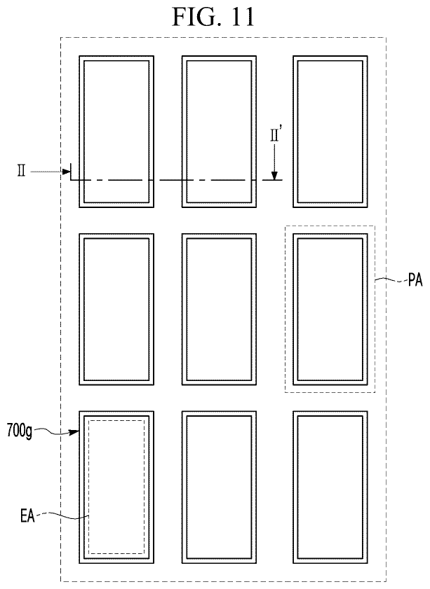

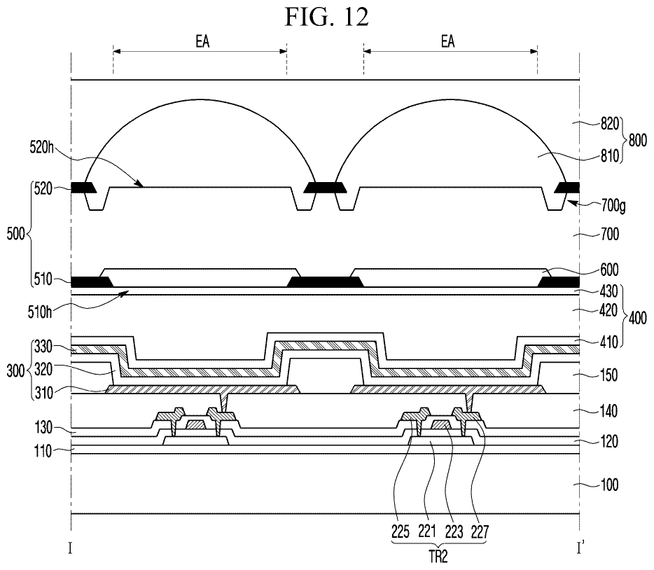

The display apparatus according to the embodiment of the present disclosure is described that the lens groove 700g of each pixel area PA includes the bottom surface overlapping with the emission area EA of the corresponding pixel area PA. However, in the display apparatus according to another embodiment of the present disclosure, the lens groove 700g of each pixel area PA can be disposed outside the emission area EA defined in the corresponding pixel area PA. For example, in the display apparatus according to another embodiment of the present disclosure, the lens groove 700g of each pixel area PA can extend along an edge of the emission area EA defined in the corresponding pixel area PA, as shown in FIGS. 11 and 12. For example, the emission area EA of each pixel area PA can be surrounded by the lens groove 700g of the corresponding pixel area PA. The lens groove 700g of each pixel area PA can overlap with the bank insulating layer 150. Thus, in the display apparatus according to another embodiment of the present disclosure, the light emitted from the light-emitting device 300 of each pixel area PA can pass through the upper surface of the optical insulating layer 700 surrounded by the lens groove 700g of the corresponding pixel area PA. That is, in the display apparatus according to another embodiment of the present disclosure, a boundary surface of the optical insulating layer 700 and the pixel lens 810 on each pixel area PA is not affected by the lens groove 700g on the corresponding pixel area PA. Therefore, in the display apparatus according to another embodiment of the present disclosure, the change of the light emitted from each pixel area PA, and the pixel lenses 810 can be firmly fixed on the pixel areas PA.

The display apparatus according to the embodiment of the present disclosure is described that the upper opening 520h of each pixel area PA has a same size as the lower opening 520h of the corresponding pixel area PA. However, in the display apparatus according to another embodiment of the present invention, the lower opening 510h and the upper opening 520h of each pixel area PA can have different sizes. For example, in the display apparatus according to another embodiment of the present disclosure, the upper opening 520h of each pixel area PA can have a larger size than the lower opening 510h of the corresponding pixel area PA, as shown in FIG. 12. The lens groove 700g extending along the emission area EA defined in each pixel area PA can overlap with the lower barrier pattern 510. Thus, in the display apparatus according to another embodiment of the present disclosure, the scattering of the light passing through the lower opening 510h on each pixel area PA due to the lens groove 700g of the corresponding pixel area PA can be prevented. Therefore, in the display apparatus according to another embodiment of the present disclosure, the decrease in the frontal luminance and the light extraction efficiency of each pixel area PA due to the lens groove 700g of the corresponding pixel area PA can be prevented.

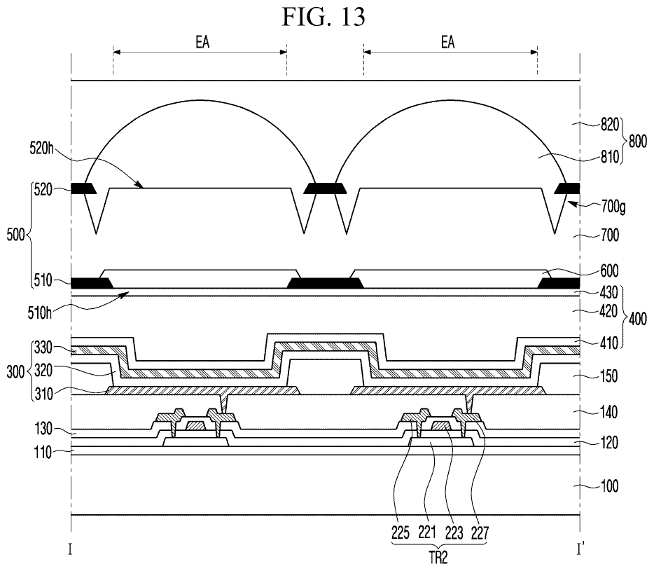

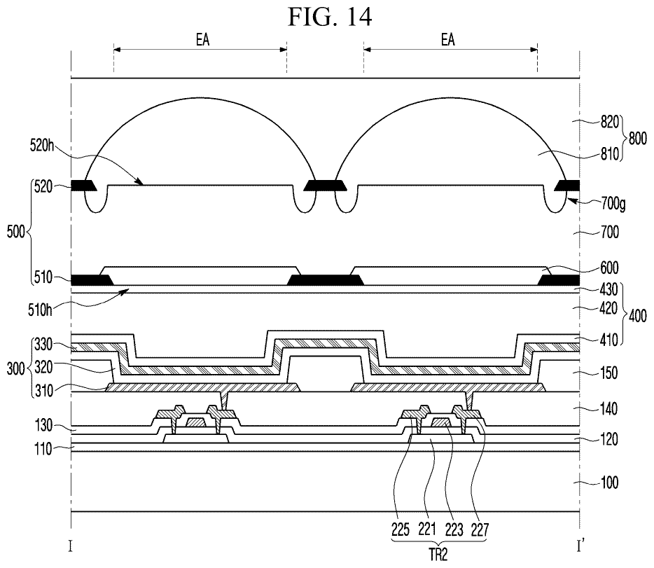

In the display apparatus according to another embodiment of the present disclosure, a cross-section of the lens groove 700g on each pixel area PA can have a polygonal shape. For example, in the display apparatus according to another embodiment of the present disclosure, a cross-section of the lens groove 700g on each pixel area PA can have a trapezoidal shape, as shown in FIG. 12. In other words, an anchoring portion can be formed along an outer edge of the lens which can extend deeper into the insulating layer 700 for an even more secure attachment. And, in the display apparatus according to another embodiment of the present disclosure, a cross-section of the lens groove 700g on each pixel area PA can have a triangular or semicircular shape, as shown in FIGS. 13 and 14 (e.g., an anchor part can have various shapes). That is, in the display apparatus according to another embodiment of the present disclosure, the lens groove 700g on each pixel area PA can be formed to have various shapes. Thus, in the display apparatus according to another embodiment of the present disclosure, the degree of freedom in the shape of each lens groove 700g disposed at the upper surface of the optical insulating layer 700 can be improved.

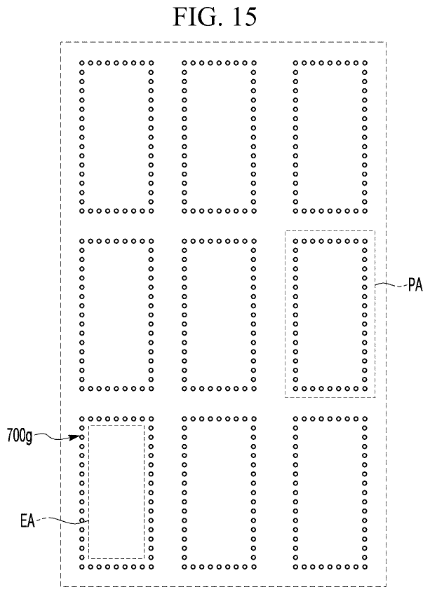

In the display apparatus according to another embodiment of the present disclosure, a plurality of lens grooves 700g can be disposed on each pixel area PA. For example, in the display apparatus according to another embodiment of the present disclosure, the emission area EA of each pixel area PA can be surrounded by the plurality of lens grooves 700g on the corresponding pixel area PA. For example, as shown in FIG. 15, each lens can have a plurality of separate anchors, teeth or spikes that extend deeper into the insulating layer 700. The plane of each lens groove 700g can have a same shape. For example, the plane of each lens groove 700g can have a circular shape. The plurality of lens grooves 700g on each pixel area PA can be spaced apart from each other. Thus, in the display apparatus according to another embodiment of the present disclosure, a contact area between the pixel lens 810 and the optical insulating layer 700 of each pixel area PA can be increased. Therefore, in the display apparatus according to another embodiment of the present disclosure, the peeling of the pixel lens 810 on each pixel area PA can be effectively prevented.

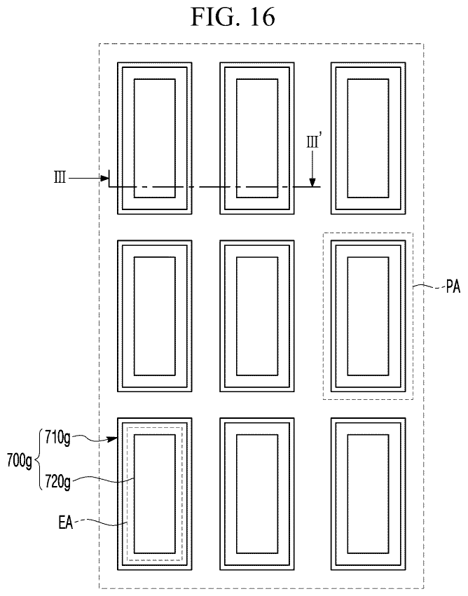

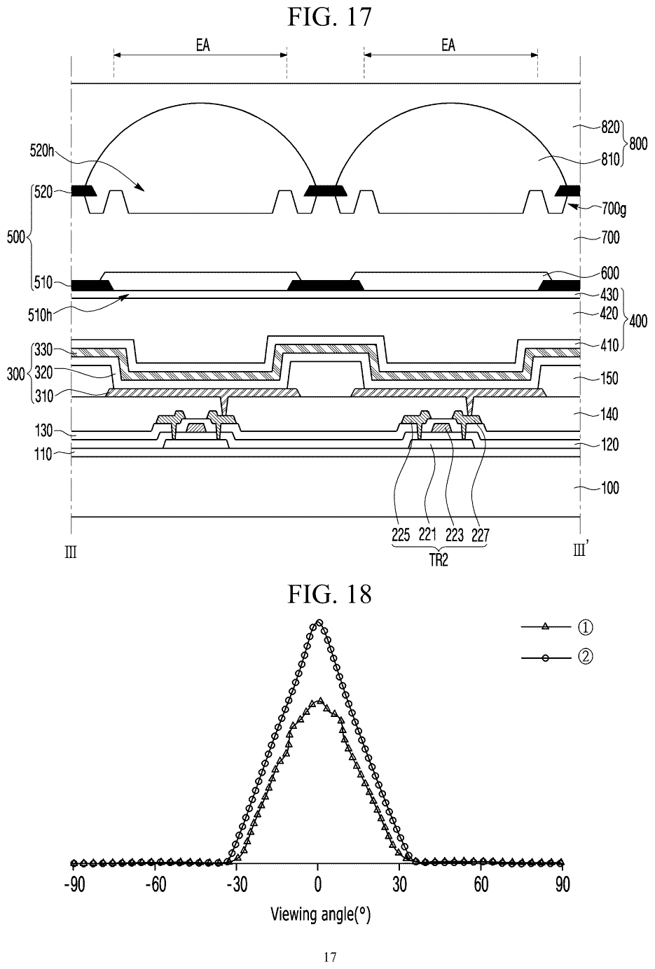

In the display apparatus according to another embodiment of the present disclosure, the lens groove 700g on each pixel area PA can include a first groove 710g surrounding the emission area EA of the corresponding pixel area PA and a second groove 720g overlapping with the emission area EA of the corresponding pixel area PA, as shown in FIGS. 16 and 17. The second groove 720g can be spaced apart from the first groove 710g. A size of the second groove 720g can be different from a size of the first groove 710g. For example, a bottom surface of the second groove 720g can have a larger size than a bottom surface of the first groove 710g. A cross-section of the second groove 720g can have a different shape from a cross-section of the first groove 710g.

A sidewall of the second groove 720 on each pixel area PA can be inclined with respect to the lower surface of the optical insulating layer 700 toward the device substrate 100. For example, a width of the second groove 720g on each pixel area PA can decrease as a distance from the device substrate 100 increases. The inclined sidewall of the second groove 720g on each pixel area PA can overlap with the emission area EA of the corresponding pixel area PA. Thus, in the display apparatus according to the embodiment of the present disclosure, the light emitted from the light-emitting device 300 of each pixel area PA can be refracted toward the center of the emission area EA defined in the corresponding pixel area PA by the inclined sidewall of the second groove 720g on the corresponding pixel area PA. That is, in the display apparatus according to another embodiment of the present disclosure, the light primarily refracted by the inclined sidewall of the second groove 720g on each pixel area PA can be secondarily refracted by the pixel lens 810 of the corresponding pixel area PA. Therefore, in the display apparatus according to another embodiment of the present disclosure, the concentration efficiency can be improved by the second groove 720g of each pixel area PA.

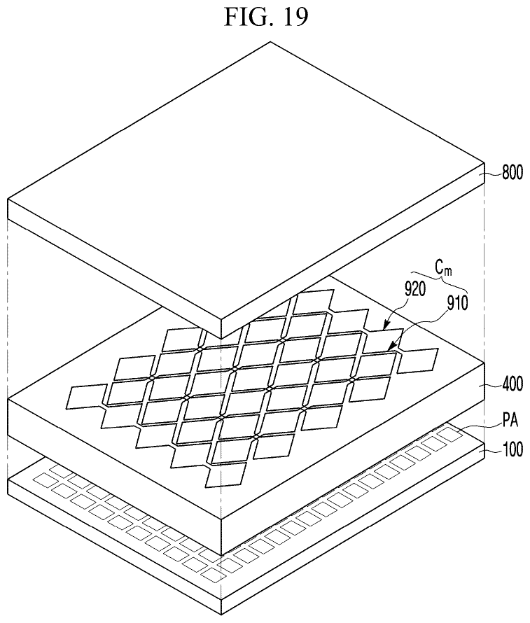

FIG. 18 is a graph showing luminance distribution in the first display apparatus \textcircled{1} in which the second groove 720g is not formed on each pixel area PA and the second display apparatus \textcircled{2} in which the second groove 720g is formed on each pixel area PA.

Referring to FIG. 18, the viewing angle of the second display apparatus \textcircled{2} can be a same as the viewing angle of the first display apparatus \textcircled{1}, and the frontal luminance of the second display apparatus \textcircled{2} can be higher than the frontal luminance of the first display apparatus \textcircled{1}. That is, in the display apparatus according to another embodiment of the present disclosure, the lens groove 700g on each pixel area PA can include the first groove 710g and the second groove 720g spaced apart from the first groove 710g, such that the frontal luminance of each pixel area PA can be increased, without the change of the viewing angle (e.g., brightness can be increased). Therefore, in the display apparatus according to another embodiment of the present disclosure, the loss of the pixel lens 810 on each pixel area PA can be prevented, and the quality of the image provided to the user can be improved. And, in the display apparatus according to another embodiment of the present disclosure, the power consumption can be reduced by the lower power driving.

As shown in FIG. 17, a sidewall of the first groove 710g on each pixel area PA can be inclined with respect to the lower surface of the optical insulating layer 700. A width of the first groove 710g on each pixel area PA can decrease as a distance from the device substrate 100 increases. For example, the inclined sidewall of the first groove 710g can have a same inclination angle as the inclined sidewall of the second groove 720g. The first groove 710g can be formed by a same process as the second groove 720g. For example, in the display apparatus according to another embodiment of the present disclosure, the first groove 710g and the second groove 720g can be formed simultaneously, before the formation of the upper barrier pattern 520. Thus, in the display apparatus according to another embodiment of the present disclosure, the decrease of the process efficiency due to the formation of the second groove 720g can be prevented. And, in the display apparatus according to another embodiment of the present disclosure, the production energy can be reduced by the process optimization.

The display apparatus according to the embodiment of the present disclosure is described that the upper barrier pattern 520 includes a same material as the lower barrier pattern 510. However, in the display apparatus according to another embodiment of the present invention, the upper barrier pattern 520 can include a different material from the lower barrier pattern 510. For example, in the display apparatus according to another embodiment of the present disclose, the upper barrier pattern 520 can include a conductive material, such as a metal.

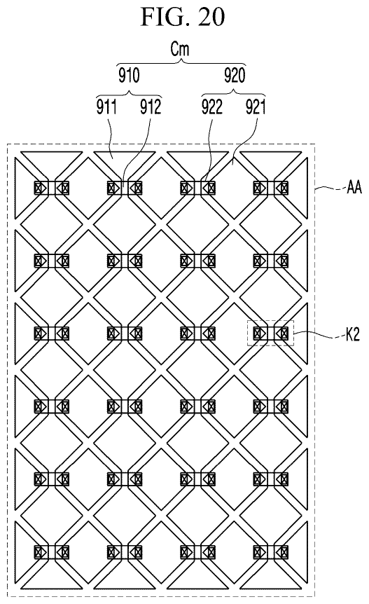

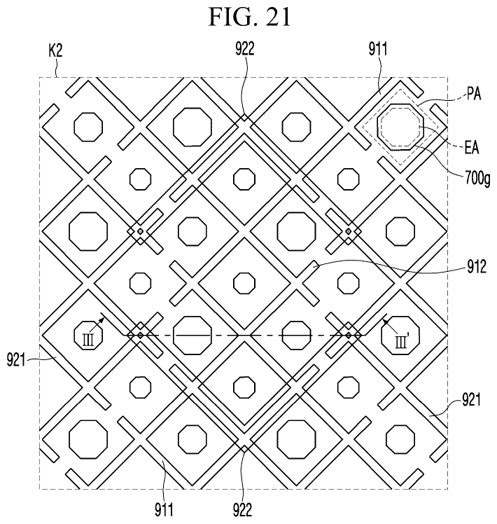

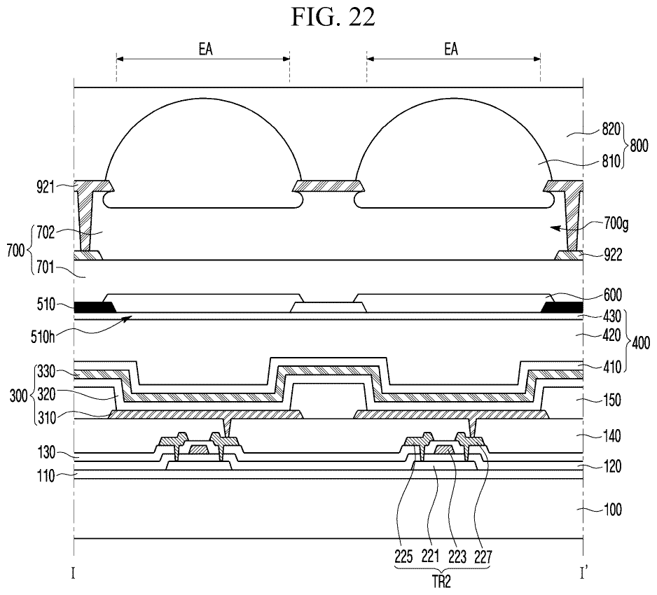

In the display apparatus according to another embodiment of the present disclosure, a touch of the user and/or a tool can be detected. For example, in the display apparatus according to another embodiment of the present disclosure, a touch sensor Cm can be disposed between the encapsulation structure 400 and the optical structure 800, as shown in FIGS. 19 to 22. The touch sensor Cm can detect presence or absence of the touch and the touch position of the user and/or the tool using the change of a mutual capacitance. For example, the touch sensor Cm can include driving touch lines 910 and sensing touch lines 920 intersecting the driving touch lines 910.

A touch driving signal can be applied in the driving touch lines 910. Each of the driving touch lines 910 can include first touch electrodes 911 and first bridge electrodes 912. The first bridge electrodes 912 can electrically connect between the first touch electrodes 911. For example, each of the driving touch lines 910 can include the first touch electrodes 911 connected in a direction by the first bride electrodes 912. A touch sensing signal can be applied in the sensing touch lines 920. Each of the sensing touch lines 920 can include second touch electrodes 921 and second bridge electrodes 922. The second touch electrodes 921 can be disposed between the first touch electrodes 911. For example, the first touch electrodes 911 and the second touch electrodes 912 can be arranged to stagger each other. Thus, in the display apparatus according to another embodiment of the present disclosure, the touch of the user and/or the tool can be sensed by using the driving touch lines 910 and the sensing touch lines 920.

The second bridge electrodes 922 can electrically connect between the second touch electrodes 921. The second touch electrodes 921 can be connected in a direction different from the first touch electrodes 911 by the second bridge electrodes 922. Each of the sensing touch lines 920 can be insulated from the driving touch lines 910. The second bridge electrodes 922 can be disposed on a different layer from the first bridge electrodes 912. For example, the optical insulating layer 700 can include a first insulating layer 701 and a second insulating layer 702 disposed on the first insulating layer 701, the second bridge electrodes 922 can be disposed between the first insulating layer 710 an the second insulating layer 702, and the first touch electrodes 911, the second touch electrodes 921 and the first bridge electrodes 912 can be disposed between the second insulating layer 702 and the optical structure 800. Each of the second bridge electrodes 922 can overlap with one of the first bridge electrodes 912.

The first touch electrodes 911, the first bridge electrodes 912, the second touch electrodes 921 and the second bridge electrodes 922 can include a conductive material. The first touch electrodes 911, the first bridge electrodes 912, the second touch electrodes 921 and the second bridge electrodes 922 can include a material having a relatively low resistance. For example, the first touch electrodes 911, the first bridge electrodes 912, the second touch electrodes 921 and the second bridge electrodes 922 can include a metal, such as copper (Cu), molybdenum (Mo), titanium (Ti) and Tantalum (Ta).

The first touch electrodes 911, the first bridge electrodes 912, the second touch electrodes 921 and the second bridge electrodes 922 of the touch sensor Cm can be disposed in the active area AA. The first touch electrodes 911, the first bridge electrodes 912, the second touch electrodes 921 and the second bridge electrodes 922 can be disposed outside the emission area EA defined in each pixel area PA. For example, the first touch electrodes 911, the first bridge electrodes 912, the second touch electrodes 921 and the second bridge electrodes 922 can overlap with the bank insulating layer 150. The plane of each first touch electrode 911 and the plane of each second touch electrode 921 can have a mesh shape including openings overlapping with the emission area EA of each pixel area PA. Thus, in the display apparatus according to another embodiment of the present disclosure, the decrease in the light extraction efficiency due to the driving touch lines 910 and the sensing touch lines 920 of the touch sensor Cm can be minimized.

The driving touch lines 910 and the sensing touch lines 920 of the touch sensor Cm can restrict the travelling direction of the light emitted from the light-emitting device 300 of each pixel area PA. For example, the driving touch lines 910 and the sensing touch lines 920 can function as barrier pattern. The first touch electrodes 911, the first bridge electrodes 912, the second touch electrodes 921 and the second bridge electrodes 922 can overlap with the lower barrier pattern 510. The lower openings 510h of the lower barrier pattern 510 can overlap a region disposed between the first touch electrodes 911, the first bridge electrodes 912, the second touch electrodes 921 and the second bridge electrodes 922. Thus, in the display apparatus according to another embodiment of the present disclosure, the upper barrier pattern can be replaced with the first touch electrodes 911, the first bridge electrodes 912, the second touch electrodes 921 and the second bridge electrodes 922. That is, in the display apparatus according to another embodiment of the present disclosure, the upper barrier pattern is not formed. Therefore, in the display apparatus according to the embodiment of the present disclosure, the touch of the user and/or the tool can be sensed, the pixel lens 810 on each pixel area PA can be stably formed, and the production energy can be reduced by the process optimization.

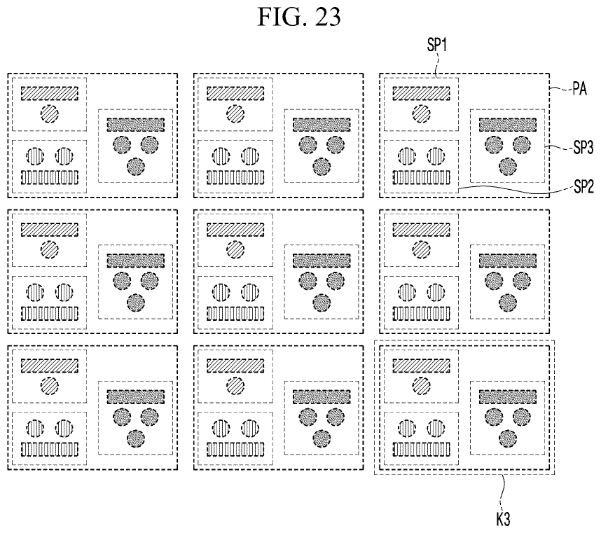

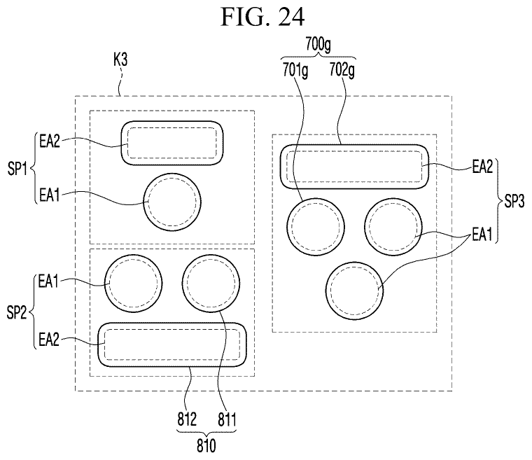

The display apparatus according to the embodiment of the present disclosure is described that a single emission area EA can be defined in each pixel area PA. However, in the display apparatus according to another embodiment of the present disclosure, a plurality of emission areas EA can be defined in each pixel area PA. For example, in the display apparatus according to another embodiment of the present disclosure, each of the pixel areas PA can include a first sub-pixel SP1, a second sub-pixel SP2, and a third sub-pixel SP3, and each of the first sub-pixel SP1, the second sub-pixel SP2 and the third sub-pixel SP3 in each pixel area PA can include at least one emission area EA1 and EA2, as shown in FIGS. 23 and 24.

The first sub-pixel SP1, the second sub-pixel SP2 and the third sub-pixel SP3 of each pixel area PA can emit light displaying different colors. For example, the first sub-pixel SP1 of each pixel area PA can emit red light, the second sub-pixel SP2 of each pixel area PA can emit green light, and the third sub-pixel SP3 of each pixel area PA can emit blue light. Thus, in the display apparatus according to another embodiment of the present disclosure, the quality of the image and brightness provided to the user can be improved.

In the display apparatus according to another embodiment of the present disclosure, the viewing angle of the image provided to the user can be adjusted. For example, each of the first sub-pixel SP1, the second sub-pixel SP2 and the third sub-pixel SP3 can include a first emission area EA1 and at least one second emission area EA2. The second emission area EA2 of each sub-pixel SP1, SP2 and SP3 can be driven independently of the first emission area EA1 of the corresponding sub-pixel SP1, SP2 and SP3. For example, the first emission area EA1 of each sub-pixel SP1, SP2 and SP3 can be driven simultaneously with the first emission area EA1 of adjacent sub-pixel SP1, SP2 and SP3, and the second emission area EA2 of each sub-pixel SP1, SP2 and SP3 can be driven simultaneously with the second emission area EA2 of adjacent sub-pixel SP1, SP2 and SP3. The plane of the second emission area EA2 can have a smaller size than the plane of the first emission area EA1. For example, the plane of the first emission area EA1 can have a bar shape extending in a first direction, and the plane of each second emission area EA2 can have a circular shape. Thus, in the display apparatus according to another embodiment of the present disclosure, the image realized by the first emission area EA1 of each sub-pixel SP1, SP2 and SP3 can have a wider viewing angle in the first direction than the image realized by the second emission area EA2 of each sub-pixel SP1, SP2 and SP3.

The pixel lens 810 of each pixel area PA can include first lenses 811 on the first emission areas EA1 of the corresponding pixel area PA and second lenses 812 on the second emission areas EA2 of the corresponding pixel area PA. The plane of each first lens 811 can have a shape corresponding to the plane of each first emission area EA1, and the plane of each second lens 812 can have a shape corresponding to the plane of each second emission area EA2. For example, the plane of each first lens 811 can have a bar shape extending in the first direction (e.g., a rounded, rectangular shape), and the plane of each second lens 812 can have a circular shape (e.g., a dome shape or hemispherical shape).

The lens groove 700g of each pixel area PA can include first sub-grooves 701g on the first emission areas EA1 of the corresponding pixel area PA and second sub-grooves 702g on the second emission areas EA2 of the corresponding pixel area PA. Each of the first sub-grooves 701g can overlap with one of the first emission areas EA1. Each of the second sub-grooves 702g can overlap with one of the second emission areas EA2. Thus, in the display apparatus according to another embodiment of the present disclosure, the first lenses 811 on the first emission areas EA1 of each pixel area PA can be fixed by the first sub-grooves 701g of the corresponding pixel area PA, and the second lenses 812 on the second emission areas EA2 of each pixel area PA can be fixed by the second sub-grooves 702g. Therefore, in the display apparatus according to another embodiment of the present disclosure, the peeling of the first lenses 811 and the second lenses 812 on each pixel area PA due to the external impact can be prevented, regardless of the viewing angle of the image provided to the user.

In the result, the display apparatus according to the embodiments of the present disclosure can include the optical insulating layer on the light-emitting device, the barrier pattern on the optical insulating layer, and the pixel lens on the barrier pattern, in which the barrier pattern can include the opening overlapping with the emission area in which the light-emitting device is disposed, in which the optical insulating layer can include the lens groove overlapping with the end of the barrier pattern toward the emission area, and in which the pixel lens including a region overlapping with the opening can surround the end of the barrier pattern overlapping with the lens groove. Thus, in the display apparatus according to the embodiments of the present disclosure, the peeling of the pixel lens due to the external impact can be prevented by the end of the barrier pattern. That is, in the display apparatus according to the embodiments of the present disclosure, the pixel lens can be stably formed on the pixel area. Thereby, in the display apparatus according to the embodiments of the present disclosure, the production energy can be reduced by the process optimization.

What is claimed is:

1. A display apparatus comprising:
a light-emitting device on an emission area of a device substrate;
a lower barrier pattern on the light-emitting device, the lower barrier pattern including a lower opening overlapping with the emission area;
an upper barrier pattern on the lower barrier pattern, the upper barrier pattern including an upper opening overlapping with the lower opening;
a pixel lens on the upper barrier pattern, the pixel lens overlapping with the emission area; and
an optical insulating layer disposed between the lower barrier pattern and the upper barrier pattern, the optical insulating layer including a lens groove filled by the pixel lens,
wherein the lens groove overlaps with an end of the upper barrier pattern.

2. The display apparatus according to claim 1, wherein a size of the upper opening of the upper barrier pattern is different than a size of the lower opening of the lower barrier pattern.

3. The display apparatus according to claim 1, wherein the lens groove is wider than the upper opening, and a bottom surface of the lens groove overlaps with the emission area.

4. The display apparatus according to claim 3, wherein the bottom surface of the lens groove overlapping with the emission area has a flat shape.

5. The display apparatus according to claim 3, wherein the lens groove includes a sidewall overlapping with the upper barrier pattern, and
wherein the sidewall of the lens groove overlapping with the upper barrier pattern has a curved shape.

6. The display apparatus according to claim 1, wherein a lower surface of the upper barrier pattern is in contact with the pixel lens in the lens groove.

7. The display apparatus according to claim 1, wherein the upper barrier pattern includes a different material from the lower barrier pattern.

8. The display apparatus according to claim 7, wherein the upper barrier pattern includes a conductive material.

9. A display apparatus comprising:
a light-emitting device on an emission area;
an optical insulating layer on the light-emitting device, the optical insulating layer including a first lens groove in an upper surface of the optical insulating layer;
an upper barrier pattern on the optical insulating layer, the upper barrier pattern including an upper opening overlapping with the emission area; and
a pixel lens on the upper barrier pattern, the pixel lens overlapping with the upper opening,
wherein the upper barrier pattern includes an end overlapping with the first lens groove, and
wherein the end of the upper barrier pattern overlapping with the first lens groove is surrounded by the pixel lens.

10. The display apparatus according to claim 9, wherein the first lens groove extends along an edge of the emission area.

11. The display apparatus according to claim 9, wherein the optical insulating layer includes a second lens groove spaced apart from the first lens groove,
wherein the second lens groove overlaps with the upper opening of the upper barrier pattern,
wherein a sidewall of the second lens groove has an inclined shape with respect to a lower surface of the optical insulating layer, and
wherein a width of the second lens groove increases in a direction towards the pixel lens.

12. The display apparatus according to claim 11, wherein a bottom surface of the second lens groove has a flat shape.

13. The display apparatus according to claim 11, wherein a size of the second lens groove is different from a size of the first lens groove.

14. The display apparatus according to claim 13, wherein a sidewall of the first lens groove has an inclined shape with respect to the lower surface of the optical insulating layer, and
wherein the sidewall of the second lens groove has a same inclination angle as the sidewall of the first lens groove.

15. The display apparatus according to claim 9, further comprising:
an encapsulation structure disposed between the optical insulating layer and the light-emitting device, the encapsulation structure covering the light-emitting device; and
a lower barrier pattern disposed between the encapsulation structure and the optical insulating layer, the lower barrier pattern including a lower opening overlapping with the emission area,
wherein the first lens groove is outside the lower opening of the lower barrier pattern.

16. A display apparatus comprising:
a light-emitting device configured to emit light;
a light blocking layer disposed on the light-emitting device, the light blocking layer including an opening overlapping with an emission area of the light-emitting device;
an optical insulating layer disposed between the light-emitting device and the light blocking layer, the optical insulating layer including a lens groove; and
a lens disposed in the lens groove of the optical insulating layer,
wherein a portion of the lens is disposed between an edge of the light blocking layer and the optical insulating layer.

17. The display apparatus according to claim 16, wherein the edge of the light blocking layer and a sidewall of the lens groove in the optical insulating layer form an undercut area below a portion of the light blocking layer, and
wherein a portion of the lens is disposed in the undercut area.

18. The display apparatus according to claim 17, wherein a side region of the lens contacts an upper surface of the light blocking layer, the edge of the light blocking layer, and a lower surface of the light blocking layer.

19. The display apparatus according to claim 16, wherein the lens includes an anchor portion extending into the optical insulating layer.

20. The display apparatus according to claim 16, wherein an inner edge of the opening in the light blocking layer forms a ringed clamp around the lens, or an inner periphery of the opening in the light blocking layer is configured to circumferentially encompass and retain the lens.
